(19) United States
(12) Patent Application Publication
(10) Pub. No.: US 2026/0271348 A1
(43) Pub. Date: Sep. 10, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Keng-Ying LIAO, Tainan City (TW); Po-Zen CHEN, Tainan City (TW); Chih Wei SUNG, Kaohsiung City (TW); Chen-Chi HSIAO, Taipei City (TW); Guan-Qi CHEN, Kaohsiung City (TW)

(73) Assignee: TAIWAN SEMICONDUCTOR MANUFACTURING COMPANY, LTD., Hsinchu (TW)

(21) Appl. No.: 19/072,853

(22) Filed: Mar. 6, 2025

(51) Int. Cl. H10D 62/10; H10D 86/00

(52) U.S. Cl. CPC H10D 62/102; H10D 86/201

(57) ABSTRACT

A semiconductor device includes a substrate comprising a base semiconductor layer, an insulator layer over the base semiconductor layer, and an active semiconductor layer over the base semiconductor layer, wherein the active semiconductor layer has an active region. A shallow trench isolation (STI) structure is in the substrate and adjacent to the active region. A deep trench isolation (DTI) structure extends through the STI structure, wherein the DTI structure comprises a conductive material and an isolation liner lining a sidewall of the conductive material, and wherein the isolation liner has a multilayer structure.

### BACKGROUND

Modern day integrated chips comprise millions or billions of semiconductor devices formed on a semiconductor substrate (e.g., silicon). Integrated chips (ICs) may use many different types of semiconductor devices, depending on an application of an IC. To reduce the area of the IC, the semiconductor devices may be formed in close proximity to one another. To prevent interference amongst the semiconductor devices, techniques and/or features for device isolation in ICs are being researched. Among other things, deep trench isolation structures are a promising candidate to provide electrical isolation amongst semiconductor devices to improve device performance without sacrificing a large area on the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 10 illustrate a method in various stages of forming a semiconductor device in accordance with some embodiments of the present disclosure.

FIG. 11 illustrates a cross-sectional view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

In some applications, more than one semiconductor device may be integrated onto a same substrate. However, current leakage, cross-talk between the semiconductor devices, and/or eventual device performance degradation may become difficult to prevent as device size decreases and voltage operating conditions increase (e.g., greater than 100 Volts). To mitigate current leakage and device performance degradation, in some embodiments, for example, multiple semiconductor devices may be integrated on a silicon-on-insulator (SOI) substrate comprising an insulator layer between an active semiconductor layer and a base semiconductor layer. In other embodiments, to arrange semiconductor devices even closer to one another and provide more reliable device isolation, isolation structures may be formed to electrically separate the semiconductor devices from one another. For example, a deep trench isolation (DTI) structure filled with a conductive material, such as polysilicon, may be formed to continuously surround each of the semiconductor devices. The DTI structure may extend into the base semiconductor layer such that the polysilicon contacts the base semiconductor layer of the SOI substrate. The conductive material may be grounded to the base semiconductor layer of the SOI substrate during operation in order to achieve electrical isolation and improve device performance. However, due to corona discharge, the SOI substrate may suffer from high voltage leakage at the bottom corner edge of the active semiconductor layer, which will inversely affect the device performance. Accordingly, embodiments of the present disclosure provide a structure and a formation method thereof to address the above issues.

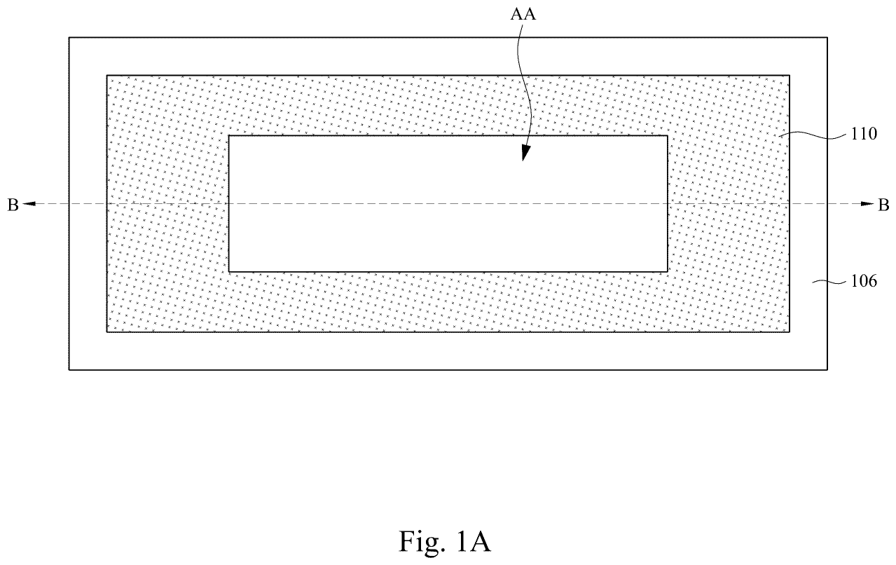

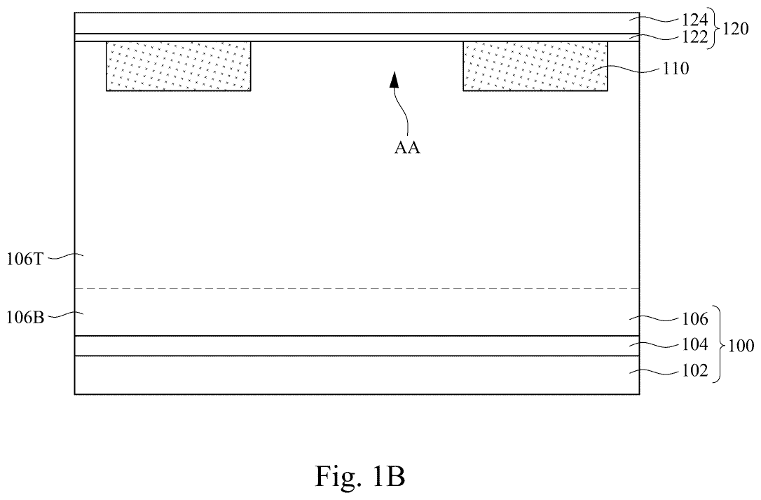

FIGS. 1A to 10 illustrate a method in various stages of forming a semiconductor device in accordance with some embodiments of the present disclosure. In greater detail, FIGS. 1A, 2A, and 9A are top views of a semiconductor device, and FIGS. 1B, 2B, 3-8, and 9B are cross-sectional views of a semiconductor device. Although FIGS. 1A to 10 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 1A and 1B, in which FIG. 1A is a top view of a semiconductor device, and FIG. 1B is a cross-sectional view along line B-B of FIG. 1A. It is noted that some elements of FIG. 1B are not illustrated in FIG. 1A for clarity. Shown there is a silicon-on-insulator (SOI) substrate 100. In some embodiments, the SOI substrate 100 includes a base semiconductor layer 102, an active semiconductor layer 106 arranged over the base semiconductor layer 102, and an insulator layer 104 arranged between the active semiconductor layer 106 and the base semiconductor layer 102. In some embodiments, the base semiconductor layer 102 comprises a monocrystalline semiconductor material (e.g., silicon, germanium, etc.). Similarly, the active semiconductor layer 106 may also comprise a semiconductor material, such as for example, silicon, germanium, or the like. In some embodiments, the base semiconductor layer 102 may include an N-type semiconductor material, for example. In some other embodiments, the SOI substrate 101 may be some other type of substrate and comprise any type of semiconductor body (e.g., silicon/CMOS bulk, SiGe, etc.). In some embodiments, the insulator layer 104 may include a dielectric material, such as silicon oxide, silicon nitride, or the like. In some embodiments, the thickness of the insulator layer 104 is about 0.1 μm to about 0.5 μm (e.g., 0.3 μm). In some embodiments, the thickness of the active semiconductor layer 106 is about 4.0 μm to about 5.0 μm (e.g., 4.5 μm). In some embodiments, the active semiconductor layer 106 may be a doped with n-type dopants or p-type dopants. In some embodiments, the active semiconductor layer 106 may include a top portion 106T and a bottom portion 106B below the top portion 106T, in which the bottom portion 106B may include a higher dopant concentration than the top portion 106T.

A shallow trench isolation (STI) structure 110 is formed in the active semiconductor layer 106 of the SOI substrate 100. In some embodiments, the STI structure 110 may include a rectangular ring shape top profile as shown in FIG. 1A, and the STI structure 110 may surround an active region AA of the active semiconductor layer 106. In some embodiments, the STI structure may each comprise an insulator and/or dielectric material, such as, for example, silicon oxide, silicon nitride, silicon oxynitride, the like, or combinations thereof. The STI structure 110 may be formed by, for example, patterning the active semiconductor layer 106 of the SOI substrate 100 to form a trench in the active semiconductor layer 106, filling the trench with one or more dielectric materials, and then performing a planarization process (e.g., CMP) to remove excess dielectric materials until the active semiconductor layer 106 is exposed.

A hard mask structure 120 is then formed over the active semiconductor layer 106 of the SOI substrate 100 and covering the STI structure 110. In some embodiments, the hard mask structure 120 may include a first dielectric layer 122 and a second dielectric layer 124 over the first dielectric layer 122, in which the first dielectric layer 122 and the second dielectric layer 124 are made of different dielectric materials. For example, the first dielectric layer 122 may be silicon nitride, and the second dielectric layer 124 may be silicon oxide. In some embodiments, the second dielectric layer 124 is thicker than the first dielectric layer 122. In some embodiments, the thickness of the first dielectric layer 122 may be about 0.15 μm and to about 0.2 μm, such as 0.16 μm. On the other hand, the thickness of the second dielectric layer 124 may be about 0.5 μm to about 1 μm, such as 0.6 μm. It will be appreciated that other values are also within the scope of the disclosure. In some embodiments, the first dielectric layer 122 and the second dielectric layer 124 may be formed by one or more deposition techniques (e.g., physical vapor deposition (PVD), chemical vapor deposition (CVD), PE-CVD, atomic layer deposition (ALD), sputtering, etc.).

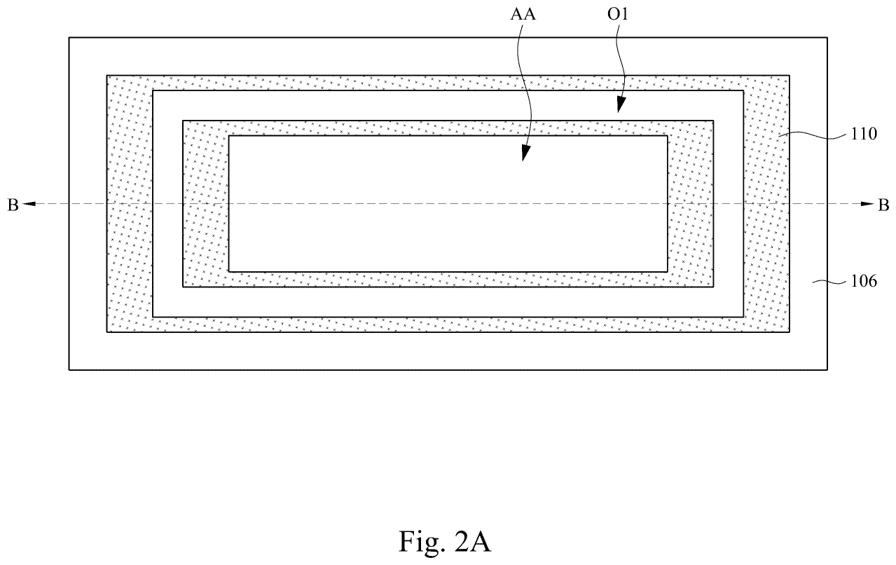

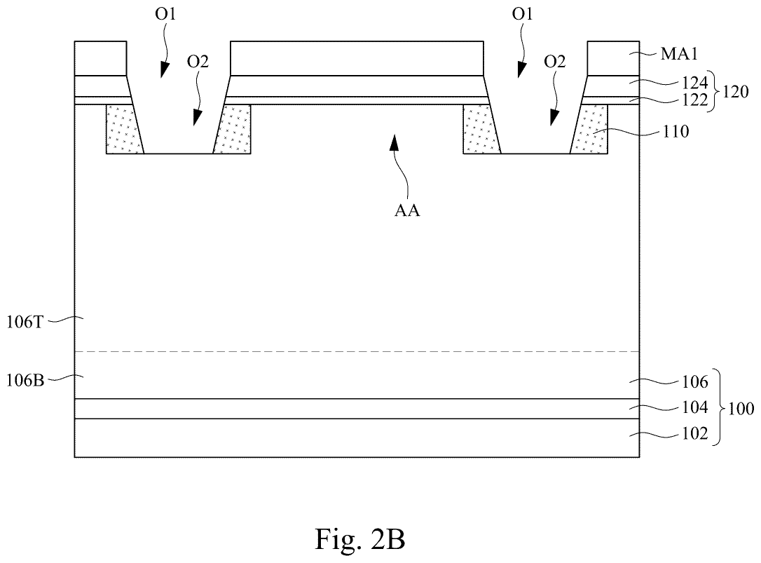

Reference is made to FIGS. 2A and 2B, in which FIG. 2A is a top view of a semiconductor device, and FIG. 2B is a cross-sectional view along line B-B of FIG. 2A. It is noted that some elements of FIG. 2B are not illustrated in FIG. 2A for clarity. A patterned mask MA1 is formed over the hard mask structure 120. The patterned mask MA1 comprises an opening O1 that directly overlies the STI structure 110. In some embodiments, the opening O1 has a width W1 that is less than a width W2 of the STI structure 110. In some embodiments, the patterned mask MA1 comprises a photoresist material deposited via a spin coating process. The patterned mask MA1 may then be selectively exposed to a radiation according to a photomask. The radiation modifies a solubility of exposed regions within the patterned mask MA1 to define soluble regions. The patterned mask MA1 is subsequently developed to define the opening O1 after removing the soluble regions.

A first removal process is performed to remove portions of the hard mask structure 120 and the STI structure 110 through the opening O1 of the patterned mask MA1, so as to form an opening O2 in the hard mask structure 120 and the STI structure 110, in which the opening O2 may expose portions of the active semiconductor layer 106 of the SOI substrate 100. In some embodiments, the first removal process comprises a dry etching process that is conducted in a substantially vertical direction. In some embodiments, a dry etchant is used during the first removal process to remove the hard mask structure 120 and the STI structure 110, whereas in other embodiments, more than one dry etchant may be used in the first removal process to remove the hard mask structure 120 and the STI structure 110.

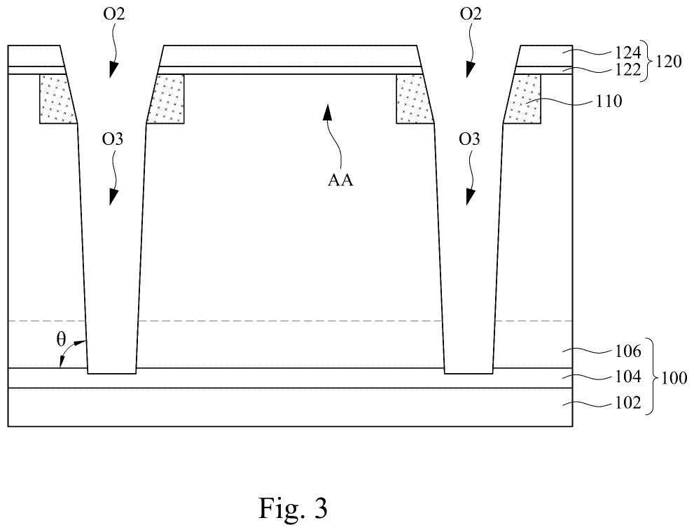

Reference is made to FIG. 3, in which FIG. 3 is a cross-sectional view following the cross-sectional view of FIG. 2B. A second removal process is performed to remove portions of the active semiconductor layer 106 of the SOI substrate 100 underlying the opening O2 of the STI structure 110, so as to form an opening O3 in the active semiconductor layer 106. In some embodiments, the second removal process is stopped when the insulator layer 104 is exposed. That is, once the second removal process is complete, the bottom end of the opening O3 is still higher than the bottom surface of the insulator layer 104. In some embodiments, the opening O3 slightly extends into the insulator layer 104, such that the bottom end of the opening O3 is lower than the top surface of the insulator layer 104. In some embodiments, the sidewall of the opening O3 is a slanting sidewall, which forms an acute angle θ with a horizontal surface (e.g., the top surface of the insulator layer 104). In some embodiments, the acute angle θ is about 89.1 degree. However, in other embodiments, the sidewall of the opening O3 may be a vertical sidewall that is substantially vertical to with a horizontal surface (e.g., the top surface of the insulator layer 104).

In some embodiments, the second removal process is or comprises a dry etching process conducted in a substantially vertical direction. In some embodiments, a dry etchant is used during the second removal process to remove the active semiconductor layer 106. In other embodiments, more than one dry etchant may be used in the second removal process.

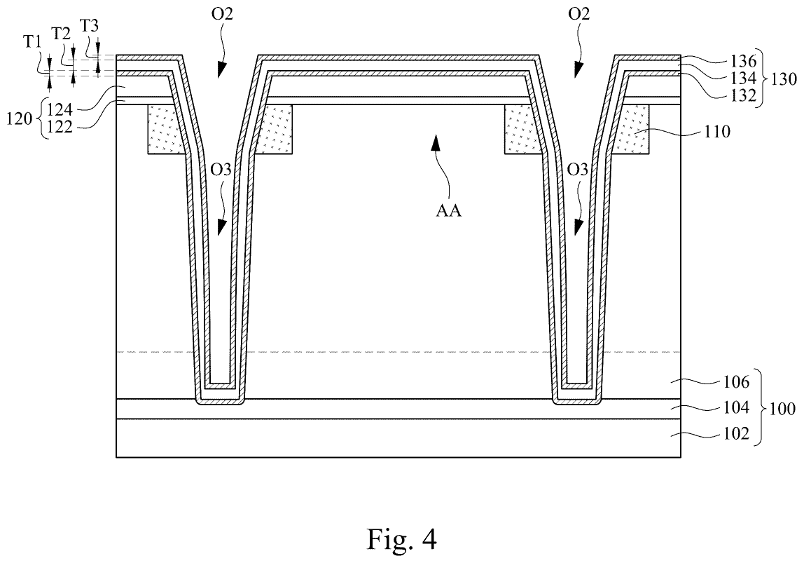

Reference is made to FIG. 4, in which FIG. 4 is a cross-sectional view following the cross-sectional view of FIG. 3. An isolation liner 130 is formed over the SOI substrate 100 and lining the opening O3 within the hard mask structure 120, the STI structure 110, the active semiconductor layer 106, and the insulator layer 104. In greater detail, the isolation liner 130 may include a first isolation layer 132, a second isolation layer 134 over the first isolation layer 132, and a third isolation layer 136 over the second isolation layer 134. The first isolation layer 132 of the isolation liner 130 may be in contact with top surface of the hard mask structure 120, sidewalls of the hard mask structure 120, sidewalls of the STI structure 110, sidewalls of the active semiconductor layer 106, and top surface of the insulator layer 104. In some embodiments, the second isolation layer 134 and the third isolation layer 136 may be spaced apart from the underlying structure through the first isolation layer 132.

In some embodiments, the first isolation layer 132, the second isolation layer 134, and the third isolation layer 136 each may be formed by a deposition process (e.g., CVD, PE-CVD, ALD, or the like). In some embodiments, the first isolation layer 132, the second isolation layer 134, and the third isolation layer 136 are made of dielectric materials, such as silicon oxide, silicon nitride, silicon oxynitride, silicon carbide, or the like. In some embodiments, the second isolation layer 134 is made of a dielectric material that is different from the materials of the first isolation layer 132 and the third isolation layer 136. In some embodiments, the first isolation layer 132 and the third isolation layer 136 are made of a same material.

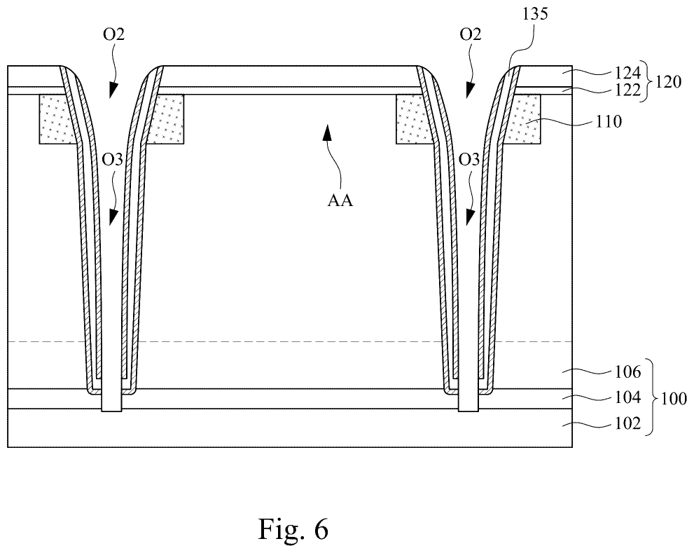

In some embodiments, the second isolation layer 134 is made of a dielectric material that has a higher dielectric constant than the materials of the first isolation layer 132 and the third isolation layer 136. For example, the first isolation layer 132 and the third isolation layer 136 are made of oxide, such as silicon oxide (SiO₂), and the second isolation layer 134 is made of nitride, such as silicon nitride (SiN). The first isolation layer 132, the second isolation layer 134, and the third isolation layer 136 may include a thickness T1, a thickness T2, and a thickness T3, respectively. In some embodiments, the thickness T2 may be greater than the thickness T1 and the thickness T3. For example, the thickness T1 and the thickness T3 each is in a range from about 40 Å to about 300 Å, and the thickness T2 is in a range from about 200 Å to about 400 Å. In some embodiments, if the thicknesses T1 and T3 are too large (e.g., much greater than 300 Å), there may not be enough space for the second isolation layer 134. If the thicknesses T1 and T3 are too small (e.g., much less than 40 Å), the first isolation layer 132 and the third isolation layer 136 may not be able to provide sufficient isolation purpose. In some embodiments, if the thickness T2 is too large (e.g., much greater than 400 Å), the second isolation layer 134 may be too thick, and may adversely affect the removal process in FIG. 6. If the thickness T2 is too small (e.g., much less than 200 Å), the second isolation layer 134 may not be able to provide sufficient etch stop and/or isolation purposes.

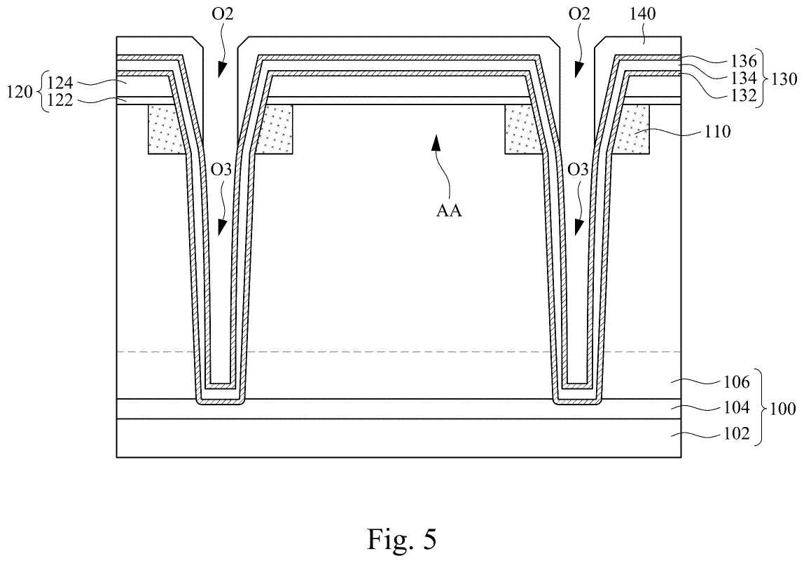

Reference is made to FIG. 5, in which FIG. 5 is a cross-sectional view following the cross-sectional view of FIG. 4. A protective layer 140 is formed over the isolation liner 130. In some embodiments, the protective layer 140 is formed with a selective manner, such that the protective layer 140 may cover top portions of the isolation liner 130, while leaving bottom portions of the isolation liner 130 exposed. In some embodiment, at least the bottom surface of the opening O3 is free of coverage by the protective layer 140. Stated another way, the horizontal portions of the isolation liner 130 extending along the top surface of the insulator layer 104 are fee of coverage by the protective layer 140. In greater detail, the protective layer 140 is in contact with top portions of the third isolation layer 136 of the isolation liner 130, while bottom portions of the third isolation layer 136 of the isolation liner 130 are exposed.

In some embodiments, the protective layer 140 may include undoped silicate glass (USG). In other embodiments, the protective layer 140 may comprise an oxide, such as, for example, silicon oxide. In some embodiments, the protective layer 140 may be made of a same material as the isolation liner 130. In other embodiments, the isolation liner 130 may comprise some other dielectric material such as silicon carbide, silicon oxide, or silicon oxynitride, for example.

In some embodiments, the deposition parameter of the protective layer 140, such as pressure, temperature, or flow rate of the precursors, can be controlled, such that the precursors of the protective layer 140 are hard to flow into the deep side of the opening O3. As a result, the protective layer 140 may include a higher deposition rate at the top portions of the isolation liner 130 than at the bottom portions of the isolation liner 130.

Reference is made to FIG. 6, in which FIG. 6 is a cross-sectional view following the cross-sectional view of FIG. 5. A third removal process is performed to remove portions of the isolation liner 130 through the opening O3, so as to form an opening O4 extending through the horizontal portions of the isolation liner 130 extending along the top surface of the insulator layer 104. The third removal process may continuously remove portions of the insulator layer 104 and the base semiconductor layer 102, such that the bottom end of the opening O4 extends into the base semiconductor layer 102. That is, the bottom end of the opening O4 may be lower than the bottom surface of the insulator layer 104. In some embodiments, the opening O4 may extend into the insulator layer 104 by, for example, about 300 Å.

On the other hand, the protective layer 140 and the horizontal portions of the isolation liner 130 extending along the top surface of the hard mask structure 120 may also be removed during the third removal process, such that the hard mask structure 120 may be exposed once the third removal process is complete. In some embodiments, due to the present of the protective layer 140, the protective layer 140 can act as a sacrificial layer to prevent over-etching to the hard mask structure 120. For example, if the protective layer 140 is absent, the third removal process will first remove the horizontal portions of the isolation liner 130 along the top surface of the hard mask structure 120 and the horizontal portions of the isolation liner 130 along the top surface of the insulator layer 104, such that the top surface of the hard mask structure 120 and the top surface of the insulator layer 104 will be exposed. When the third removal process continuously removes portions of the insulator layer 104 and the base semiconductor layer 102, the third removal process may unwantedly consume the exposed hard mask structure 120, which will adversely affect the following process.

As a result of the third removal process, vertical portions of the isolation liner 130 may remain in the opening O3. In some embodiments, the vertical portions of the isolation liner 130 may also be etched during the third removal process, and thus the remaining isolation liner 130 may taper upwardly.

In some embodiments, the third removal process comprises a dry etching process that is conducted in a substantially vertical direction. In some embodiments, a dry etchant is used during the third removal process to remove the protective layer 140, the isolation liner 130, the insulator layer 104, and the base semiconductor layer 102, whereas in other embodiments, more than one dry etchant may be used in the third removal process to remove the protective layer 140, the isolation liner 130, the insulator layer 104, and the base semiconductor layer 102.

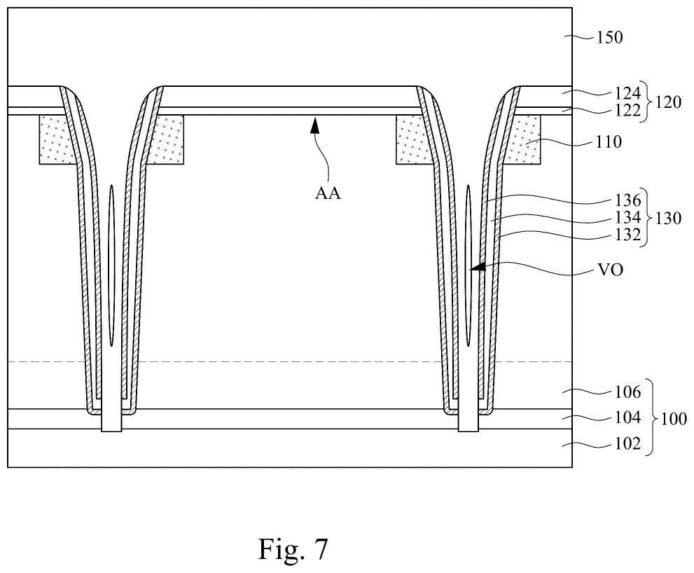

Reference is made to FIG. 7, in which FIG. 7 is a cross-sectional view following the cross-sectional view of FIG. 6. A conductive material 150 is formed over the SOI substrate 100 and filling the openings O3 and O4 (see FIG. 7). In some embodiments, the conductive material 150 may be a semiconductor material, such as polysilicon or some other suitable semiconductor material. In some embodiments, the conductive material 150 is formed by way of a deposition process (e.g., PVD, CVD, PE-CVD, low pressure CVD (LPCVD), ALD). In some embodiments, voids VO may be formed in the conductive material 150.

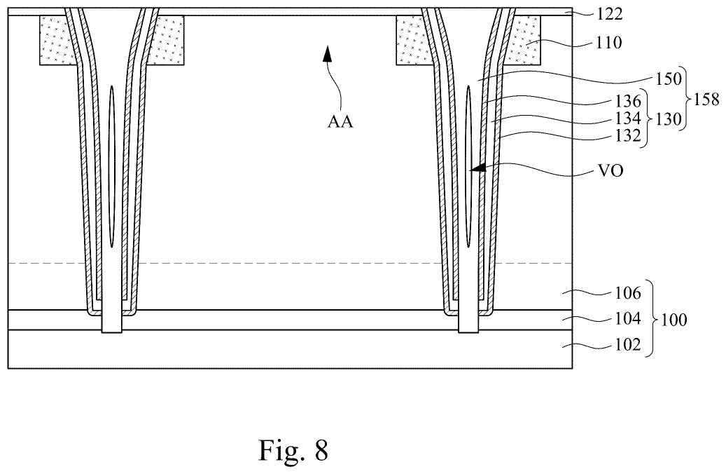

Reference is made to FIG. 8, in which FIG. 8 is a cross-sectional view following the cross-sectional view of FIG. 7. A planarization process, such as a CMP process, is performed to remove excess material of the conductive material 150. In some embodiments, the top surface of the conductive material 150 may be substantially level with the top ends of the first isolation layer 132, the second isolation layer 134, and the third isolation layer 136 of the isolation liner 130 as a result of the planarization process. However, the bottom surface of the conductive material 150 may be lower than the bottom surface of the isolation liner 130. In some embodiments, the isolation liner 130 and the conductive material 150 can be collectively referred to as a deep trench isolation (DTI) structure 158.

In some embodiments, the planarization process may be performed until the first dielectric layer 122 of the hard mask structure 120 is exposed. That is, the top surface of the conductive material 150 and the top surface of the isolation liner 130 may be substantially level with the top surface of the first dielectric layer 122. In such embodiments, the second dielectric layer 124 of the hard mask structure 120 may be removed as a result of the planarization process.

In other embodiment, the planarization process may be performed until the active semiconductor layer 106 and the STI structure 110 are exposed. That is, the top surface of the conductive material 150 and the top surface of the isolation liner 130 may be substantially level with the top surfaces of the active semiconductor layer 106 and the STI structure 110. In such embodiments, the first dielectric layer 122 and the second dielectric layer 124 of the hard mask structure 120 may be removed as a result of the planarization process.

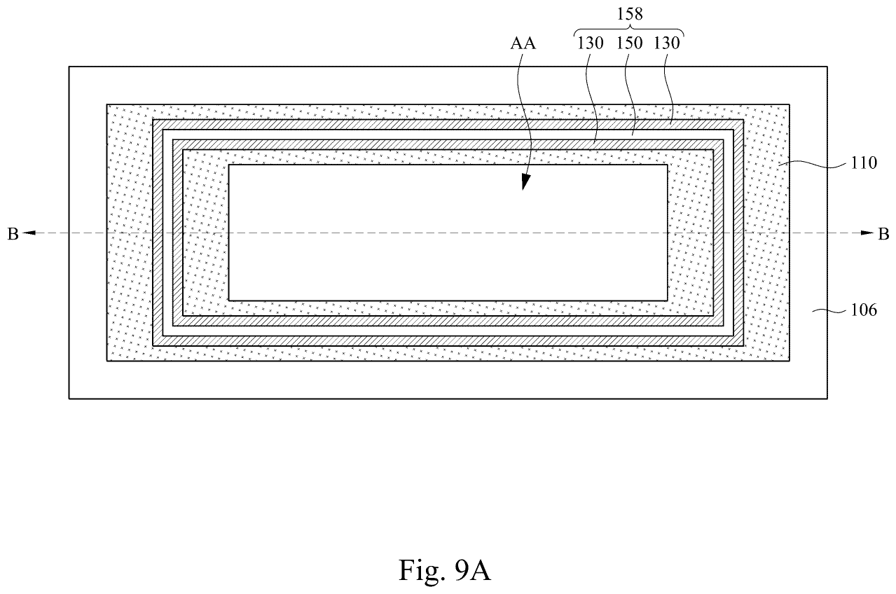

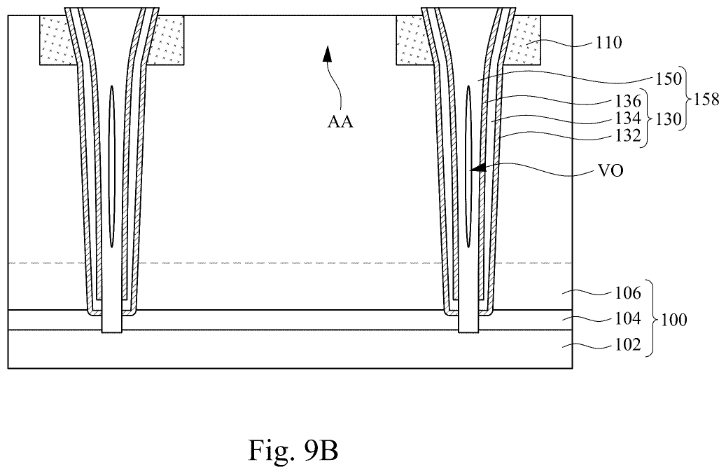

Reference is made to FIGS. 9A and 9B, in which FIG. 9A is a top view of a semiconductor device, and FIG. 9B is a cross-sectional view along line B-B of FIG. 9A. The first dielectric layer 122 is removed to expose the active semiconductor layer 106 and the STI structure 110. In greater detail, the active region AA of the active semiconductor layer 106 that is surrounded by the STI structure 110 and the isolation liner 130 may be exposed as a result of the removal of the first dielectric layer 122. In some embodiments, once the first dielectric layer 122 has been removed, the top surfaces of the isolation liner 130 and the conductive material 150 may be higher than the top surfaces of the active semiconductor layer 106 and the STI structure 110.

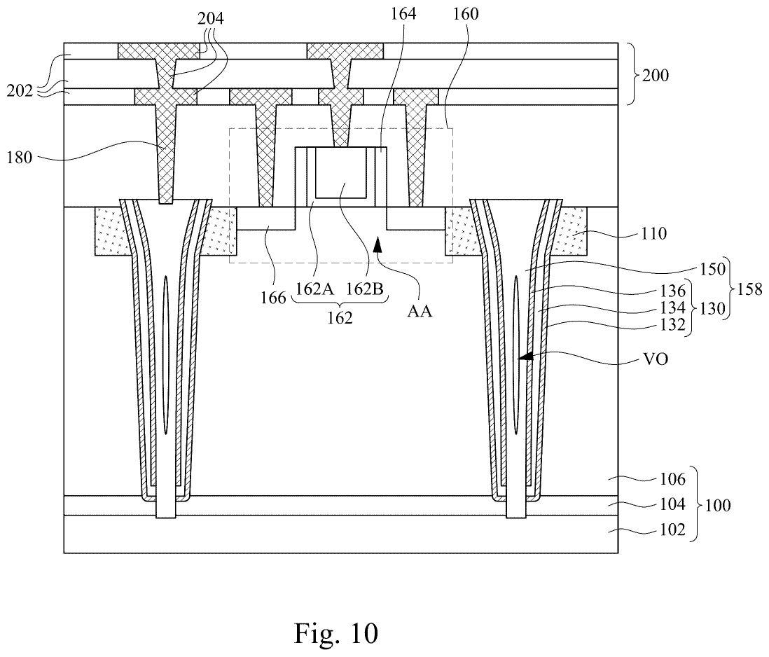

Reference is made to FIG. 10, in which FIG. 10 is a cross-sectional view following the cross-sectional view of FIG. 9B. A semiconductor device 160 is formed over the active region AA of the active semiconductor layer 106. In some embodiments, the semiconductor device 160 may be or comprise a transistor device such as a metal oxide semiconductor field effect transistor (MOSFET), whereas in other embodiments, for example, a bipolar complementary metal oxide semiconductor double diffused metal oxide semiconductor (BCD) device comprising multiple transistor devices. In some embodiments where the semiconductor device 160 is a transistor device, the semiconductor device 160 may be a planer FET, a fin-type FET (FinFET), a gate-all-around FET (GAA FET), a complementary FET (CFET), or other suitable transistor device.

In some embodiments, the semiconductor device 160 may include a gate structure 162 over the active region AA, gate spacers 164 on opposite sidewalls of the gate structure 162, and source/drain regions 166 over the active region AA and on opposite sides of the gate structure 162. In some embodiments, the gate structure 162 may include a gate dielectric layer 162A and a gate electrode 162B over the gate dielectric layer 162A.

In some embodiments, the gate dielectric layer 162A may include an interfacial layer and/or a high-k dielectric layer. The interfacial layer may be made of oxide, such as aluminum oxide (Al₂O₃), silicon oxide (SiO₂), or the like. The high-k dielectric layer may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

In some embodiments, the gate electrode 162B may include polycrystalline-silicon (polysilicon), poly-crystalline silicon-germanium (poly-SiGe), metallic nitrides, metallic silicides, metallic oxides, and metals. In other embodiments, the gate electrode 162B may include a work function metal layer and a filling metal over the work function metal layer. The work function metal layer may include n-type or p-type work function layer. The filling metal may include tungsten (W), aluminum (Al), copper (Cu), or another suitable conductive material(s).

In some embodiments, the gate spacers 164 may be formed of silicon oxide, silicon nitride, silicon oxynitride, combinations thereof. In some embodiments, the source/drain regions 166 may be doped regions in the active semiconductor layer 106, or may be epitaxial structures over the active semiconductor layer 106. The source/drain regions 166 may include n-type or p-type dopants.

An interlayer dielectric (ILD) layer 170 is formed over the SOI substrate 100 and covering the semiconductor device 160. The ILD layer 170 may be in contact with the DTI structure 158 and the STI structure 110. In greater detail, the ILD layer 170 may be in contact with the first isolation layer 132, the second isolation layer 134, and the third isolation layer 136 of the DTI structure 158. In some embodiments, the ILD layer 170 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

Conductive vias 180 are formed in the interlayer dielectric (ILD) layer 170. In some embodiments, the conductive vias 180 may include a conductive material such as aluminum, tungsten, copper, or some other suitable material. In some embodiments, the conductive vias 180 may be electrically connected to the gate structure 162 and the source/drain regions 166 of the semiconductor device 160 and the conductive material 150.

Afterwards, an interconnect structure 200 is formed over the ILD layer 170. The interconnect structure 200 may include a plurality of dielectric layers 202 stacked one above another, and may include a plurality of conductive features 204 (e.g., metal lines and metal vias) in the dielectric layers 202, respectively. In some embodiments, the conductive features 204 of the interconnect structure 200 may be electrically connected to the respective conductive vias 180.

In some embodiments, the dielectric layers 202 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The conductive features 204 may include a conductive material such as aluminum, tungsten, copper, or some other suitable material.

In some embodiments, the semiconductor device 160 may operate at high voltages. The DTI structure 158 and the STI structure 110 may collectively prevent the operating voltages of the semiconductor device 160 from leaking from the active region AA of the active semiconductor layer 106 to other devices arranged over the SOI substrate 100. Moreover, the interconnect structure 200 may be grounded to the base semiconductor layer 102 of the SOI substrate 100 through the conductive material 150 of the DTI structure 158, which improves the electrical isolation capability of the DTI structure 158 for the semiconductor device 160.

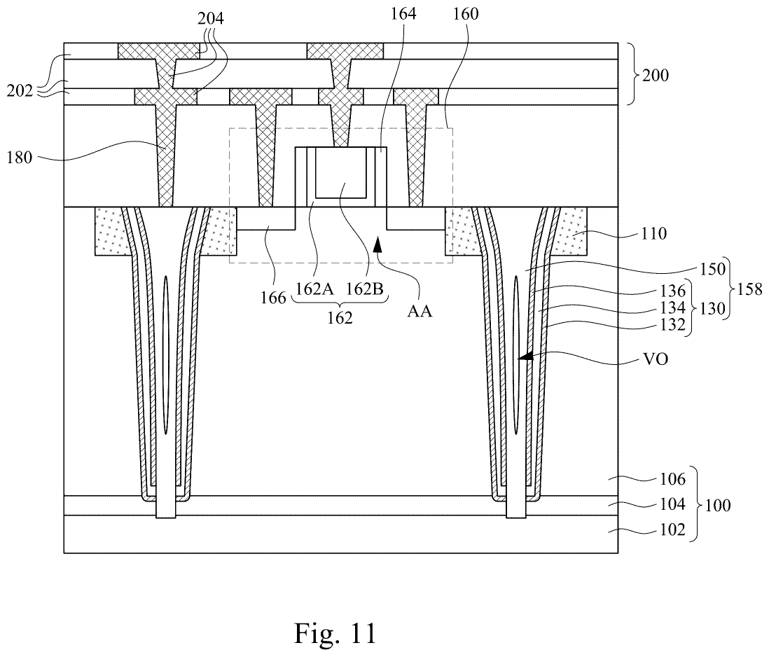

FIG. 11 illustrates a cross-sectional view of a semiconductor device in accordance with some embodiments of the present disclosure. FIG. 11 is similar to FIG. 10, thus similar elements are labeled the same, and relevant details will not be repeated for brevity. FIG. 11 is different from FIG. 10, in that the top surface of the DTI structure 158 shown in FIG. 11 is substantially level with the top surface of the STI structure 110. In greater details, the top surfaces of the first isolation layer 132, the second isolation layer 134, and the third isolation layer 136 are substantially level with the top surface of the STI structure 110. In some embodiments, the planarization process as discussed in FIG. 7 can be performed until the STI structure 110 is exposed. That is, the top surface of the conductive material 150 and the top surface of the isolation liner 130 may be substantially level with the top surface of the STI structure 110. In such embodiments, the hard mask structure 120 may be removed as a result of the planarization process.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments provide a structure and a method of a DTI structure, in which the DTI structure may include a conductive material and an isolation liner lining the conductive material. The isolation liner includes a multilayer structure to provide better isolation capability at the bottom of the DTI structure. With such configuration, the current leakage may be reduced during high voltage operation of the semiconductor device, and thus the device performance will be improved.

In some embodiments of the present disclosure, a semiconductor device includes a substrate comprising a base semiconductor layer, an insulator layer over the base semiconductor layer, and an active semiconductor layer over the base semiconductor layer, wherein the active semiconductor layer has an active region. A shallow trench isolation (STI) structure is in the substrate and adjacent to the active region. A deep trench isolation (DTI) structure extends through the STI structure, wherein the DTI structure comprises a conductive material and an isolation liner lining a sidewall of the conductive material, and wherein the isolation liner has a multilayer structure.

In some embodiments, the isolation liner comprises a first isolation layer and a second isolation layer over the first isolation layer, wherein the first isolation layer and the second isolation layer are made of different materials.

In some embodiments, the first isolation layer is made of oxide and the second isolation layer is made of nitride.

In some embodiments, the isolation liner further comprises a third isolation layer over the second isolation layer.

In some embodiments, the first isolation layer and the second isolation layer are in contact with the conductive material.

In some embodiments, a bottom surface of the conductive material is lower than a bottom surface of the isolation liner.

In some embodiments, the bottom surface of the isolation liner is higher than a bottom surface of the insulator layer of the substrate.

In some embodiments of the present disclosure, a semiconductor device includes a substrate comprising a base semiconductor layer, an insulator layer over the base semiconductor layer, and an active semiconductor layer over the base semiconductor layer, wherein the active semiconductor layer has an active region. A deep trench isolation (DTI) structure extends through the active semiconductor layer and the insulator layer into the base semiconductor layer, wherein the DTI structure comprises a conductive material and an isolation liner lining a sidewall of the conductive material. The isolation liner comprises a first isolation layer, a second isolation layer over the first isolation layer, and a third isolation layer over the second isolation layer.

In some embodiments, the second isolation layer is made of a different material than the first isolation layer and the third isolation layer.

In some embodiments, the first isolation layer and the third isolation layer are made of a same material.

In some embodiments, the first isolation layer and the third isolation layer are made of oxide and the second isolation layer is made of nitride.

In some embodiments, the second isolation layer is thicker than the first isolation layer and the third isolation layer.

In some embodiments, a material of the second isolation layer has a higher dielectric constant than materials of the first isolation layer and the third isolation layer.

In some embodiments, the first, second, and third isolation layers are in contact with the conductive material.

In some embodiments, the semiconductor device further includes a transistor over the active region of the active semiconductor layer, and an interlayer dielectric layer over the substrate and covering the transistor, wherein the first, second, and third isolation layers are in contact with the interlayer dielectric layer.

In some embodiments, the semiconductor device further includes an interconnect structure over the transistor, wherein the interconnect structure is electrically connected with the conductive material of the DTI structure.

In some embodiments of the present disclosure, a method includes performing a first removal process to a substrate having a base semiconductor layer, an insulator layer over the base semiconductor layer, and an active semiconductor layer over the base semiconductor layer, so as to form an opening in the active semiconductor layer of the substrate; forming an isolation liner along the opening, wherein forming the isolation liner comprises depositing a first isolation layer; depositing a second isolation layer over the first isolation layer; and depositing a third isolation layer over the second isolation layer; performing a second removal process to remove portions of the isolation liner and the insulator layer until the base semiconductor layer is exposed; and forming a conductive material in the opening.

In some embodiments, the first isolation layer and the third isolation layer are made of oxide and the second isolation layer is made of nitride.

In some embodiments, the method further includes prior to performing a third removal process, forming a protective layer covering a top portion of the isolation liner, while leaving a bottom portion of the isolation liner exposed.

In some embodiments, the method further includes forming a shallow trench isolation (STI) structure in the substrate prior to performing the first removal process, wherein the first removal process is performed through the STI structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate, comprising:
a base semiconductor layer;
an insulator layer over the base semiconductor layer; and
an active semiconductor layer over the base semiconductor layer, wherein the active semiconductor layer has an active region;
a shallow trench isolation (STI) structure in the substrate and adjacent to the active region; and
a deep trench isolation (DTI) structure extending through the STI structure, wherein the DTI structure comprises a conductive material and an isolation liner lining a sidewall of the conductive material, and wherein the isolation liner has a multilayer structure.

2. The semiconductor device of claim 1, wherein the isolation liner comprises:
a first isolation layer; and
a second isolation layer over the first isolation layer, wherein the first isolation layer and the second isolation layer are made of different materials.

3. The semiconductor device of claim 2, wherein the first isolation layer is made of oxide and the second isolation layer is made of nitride.

4. The semiconductor device of claim 2, wherein the isolation liner further comprises:
a third isolation layer over the second isolation layer.

5. The semiconductor device of claim 2, wherein the first isolation layer and the second isolation layer are in contact with the conductive material.

6. The semiconductor device of claim 1, wherein a bottom surface of the conductive material is lower than a bottom surface of the isolation liner.

7. The semiconductor device of claim 6, wherein the bottom surface of the isolation liner is higher than a bottom surface of the insulator layer of the substrate.

8. A semiconductor device, comprising:
a substrate, comprising:
a base semiconductor layer;
an insulator layer over the base semiconductor layer; and
an active semiconductor layer over the base semiconductor layer, wherein the active semiconductor layer has an active region;
a deep trench isolation (DTI) structure extending through the active semiconductor layer and the insulator layer into the base semiconductor layer, wherein the DTI structure comprises a conductive material and an isolation liner lining a sidewall of the conductive material, and wherein the isolation liner comprises:
a first isolation layer;
a second isolation layer over the first isolation layer; and
a third isolation layer over the second isolation layer.

9. The semiconductor device of claim 8, wherein the second isolation layer is made of a different material than the first isolation layer and the third isolation layer.

10. The semiconductor device of claim 8, wherein the first isolation layer and the third isolation layer are made of a same material.

11. The semiconductor device of claim 8, wherein the first isolation layer and the third isolation layer are made of oxide and the second isolation layer is made of nitride.

12. The semiconductor device of claim 8, wherein the second isolation layer is thicker than the first isolation layer and the third isolation layer.

13. The semiconductor device of claim 8, wherein a material of the second isolation layer has a higher dielectric constant than materials of the first isolation layer and the third isolation layer.

14. The semiconductor device of claim 8, wherein the first, second, and third isolation layers are in contact with the conductive material.

15. The semiconductor device of claim 8, further comprising:
a transistor over the active region of the active semiconductor layer; and
an interlayer dielectric layer over the substrate and covering the transistor, wherein the first, second, and third isolation layers are in contact with the interlayer dielectric layer.

16. The semiconductor device of claim 15, further comprising an interconnect structure over the transistor, wherein the interconnect structure is electrically connected with the conductive material of the DTI structure.

17. A method, comprising:
performing a first removal process to a substrate having a base semiconductor layer, an insulator layer over the base semiconductor layer, and an active semiconductor layer over the base semiconductor layer, so as to form an opening in the active semiconductor layer of the substrate;
forming an isolation liner along the opening, wherein forming the isolation liner comprises:
depositing a first isolation layer;
depositing a second isolation layer over the first isolation layer; and
depositing a third isolation layer over the second isolation layer;
performing a second removal process to remove portions of the isolation liner and the insulator layer until the base semiconductor layer is exposed; and
forming a conductive material in the opening.

18. The method of claim 17, wherein the first isolation layer and the third isolation layer are made of oxide and the second isolation layer is made of nitride.

19. The method of claim 17, further comprising, prior to performing a third removal process, forming a protective layer covering a top portion of the isolation liner, while leaving a bottom portion of the isolation liner exposed.

20. The method of claim 19, further comprising forming a shallow trench isolation (STI) structure in the substrate prior to performing the first removal process, wherein the first removal process is performed through the STI structure.
